(19) United States
(12) Patent Application Publication
(10) Pub. No.: US 2010/0295188 A1
(43) Pub. Date: Nov. 25, 2010

(54) SEMICONDUCTOR DEVICE HAVING DEEP CONTACT STRUCTURE AND METHOD OF MANUFACTURING THE SAME

(75) Inventors: Ky Hyun HAN, Gyeonggi-do (KR); Jae Min LEE, Gyeonggi-do (KR)

Correspondence Address: LADAS & PARRY LLP, 224 SOUTH MICHIGAN AVENUE, SUITE 1600, CHICAGO, IL, 60604, US

(73) Assignee: HYNIX SEMICONDUCTOR INC., Gyeonggi-do (KR)

(21) Appl. No.: 12/635,935

(22) Filed: Dec. 11, 2009

(30) Foreign Application Priority Data
May 20, 2009 (KR) 10-2009-0043828

(51) Int. Cl. H01L 23/48; H01L 21/768

(52) U.S. Cl. 257/774; 438/637; 257/E21.585; 257/E23.011

(57) ABSTRACT

A semiconductor device having a deep contact structure having an improved contact resistance is presented. The semiconductor device includes a semiconductor substrate, a first interlayer insulating layer, a contact plug, a second interlayer insulating layer, and a copper contact pad. The contact plug is formed in the first interlayer insulating layer and has a bulbous shaped upper side wall and an inwardly tapered lower side wall that extends downward towards the semiconductor substrate. The second interlayer insulating layer is formed over first interlayer insulating layer such that the second interlayer insulating layer includes a hole that exposes a top surface and a peripheral portion of the bulbous shaped upper side wall of the contact plug. The copper contact pad is buried within the hole so that the exposed parts of the bulbous shaped upper side wall of the contact plug protrude into the copper contact pad.

### CROSS-REFERENCES TO RELATED PATENT APPLICATION

The present application claims priority under 35 U.S.C 119(a) to Korean Application No. 10-2009-0043828, filed on May 20, 2009, in the Korean Intellectual Property Office, which is incorporated herein by reference in its entirety as set forth in full.

### BACKGROUND

1. Technical Field

The embodiment described herein relates to a semiconductor device and a method of manufacturing the same, and more particularly, to a semiconductor device with an interconnection line structure having a high aspect ratio and a method of manufacturing the same.

2. Related Art

As technological development continuously advances in a semiconductor manufacturing field, high-integration semiconductor devices having higher element density, lower power consumption, and higher operation speed are being developed. The high-integration semiconductor devices are adopting a multilayered wiring structure for electrical connection of circuit patterns.

The multilayered wiring structure is acquired by continuous vertical placement of a contact plug formed in a via hole and a contact pad disposed on the contact plug.

Currently, a tungsten (W) metallic material having a superior space filling characteristic is used as the contact plug and an aluminum alloy film (Al-alloy) or a copper (Cu) metal film having a superior resistivity characteristic is used as the contact pad.

In general, the Al-alloy film has an advantage in that it is easy to pattern, but the Al-alloy film has a disadvantage in that it has a lower current transmission characteristic than the copper metal film and is not stable for heat. Meanwhile, the copper metal film has thermal stability and a high current transmission characteristic by a low resistivity characteristic, but the copper metal film cannot be patterned by the existing etching process.

Currently, a damascene process is proposed for patterning the copper metal film in the semiconductor device and the copper metal film is used as a metal wiring material by using the damascene process.

FIG. 1 is a diagram illustrating one example using a copper metal film as a wiring material.

Referring to FIG. 1, a first interlayer insulating layer 20 is formed on the top of a semiconductor substrate 10 including a circuit pattern (not shown). A contact hole (not shown) is formed in the first interlayer insulating layer 20 and a contact plug 30 is formed by filling a buried metal film, i.e., a tungsten metal film in the contact hole. Thereafter, a second interlayer insulating layer 40 is formed on the top of the first interlayer insulating layer 20 where the contact plug 30 is formed and a damascene contact hole (not shown) is formed by etching the second interlayer insulating layer 40 so as to expose the contact plug 30 and a peripheral portion thereof. At this time, etching for forming the damascene contact hole may excessively be performed in order to completely expose the contact plug 30 and increase a contact area. As a result, the top of the contact plug 30 and upper side walls may partially be exposed. Next, the copper metal film is deposited so as to fill the damascene contact hole and the copper metal film is chemically and mechanically ground so as to form a copper pad 50. As is known in the related art, in the case of the copper metal film, after a copper seed layer 50a is formed on the inner wall of the damascene contact hole, the copper metal film 50 is deposited based on the copper seed layer 50a.

However, since the width of the contact plug 30 of the high-integration semiconductor device decreases to the level of exposure limits or less, an aspect ratio of the contact plug 30 is gradually increased. Further, etching gas for forming the contact hole (not shown) is not fully delivered toward the bottom of the first interlayer insulating layer 20, such that the side wall of the contact plug 30 has a negative slope. In particular, the side wall of a contact plug having a very deep depth such as a word line contact portion of a phase-change memory device has a further steep slope.

When the copper seed layer 50a is deposited on the exposed surface of the contact plug 30 having the negative slope, the copper seed layer 50a is unevenly deposited to cause an overhang due to the side wall having the negative slope. That is, the copper seed layer 50 is not almost formed on a corner formed between the first interlayer insulating layer 20 and the side wall of the contact plug 30 while the copper seed layer 50 is somewhat thickly formed on the top of the contact plug 30, such that a void V is generated at the corner as shown in FIG. 1. As described above, the void V can serve as a leakage source of the semiconductor device. Herein, the copper seed layer 50a is not generally seen after the copper metal film 50 is deposited, but the copper seed layer 50a is illustrated in FIG. 1 for convenience of description.

Further, as shown in FIG. 2, in the case of a contact structure having a deep depth, the slope of the side wall of the contact plug 30 becomes steeper, such that an upper corner portion of the contact plug 30 serves as a mask. As a result, a first interlayer insulating layer 20a that is provided on the upper side wall of the contact plug 30 can remain. Since the side wall of the contact plug 30 is shielded due to the first interlayer insulating layer 20a, a contact area of the copper pad 50 is decreased. Therefore, contact resistance is increased.

### SUMMARY

In a first aspect, a semiconductor device includes: a semiconductor substrate; a first interlayer insulating layer configured to be formed over the semiconductor substrate; a contact plug configured to be formed in the first interlayer insulating layer and have an upper side wall having a bowing shape; and a contact pad configured to be formed on the top of the contact plug.

In a second aspect, a semiconductor device includes: a semiconductor substrate; a first interlayer insulating layer configured to be formed over the semiconductor substrate; a contact plug configured to be formed in the first interlayer insulating layer and have an upper side wall and a lower side wall consecutively extending to the semiconductor substrate from the upper side wall; a second interlayer insulating layer configured to include a hole for exposing the top surface of the contact plug and a peripheral portion thereof; and a copper contact pad configured to be buried in the hole of the second interlayer insulating layer, wherein the top surface of the contact plug and a part of the upper side wall are configured to protrude into the copper contact pad, and the upper side wall of the contact plug positioned in the copper contact pad is configured to have a positive slope.

In a third aspect, a method of manufacturing a semiconductor device will be described below. A first interlayer insulating layer is formed on the top of a semiconductor substrate and a contact hole having an upper side wall having a bowing shape and a lower side wall that consecutively extends from the upper side wall and has an anisotropic shape is formed on the first interlayer insulating layer. Thereafter, after a contact plug is formed by filling up the contact hole with a metal film, a contact pad is formed on the top of the contact plug.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIGS. 1 and 2 are cross-sectional views of a general deep contact structure;

FIG. 3 is a cross-sectional view of an exemplary semiconductor device having a deep contact structure according to one embodiment; and

FIGS. 4 to 10 are cross-sectional views for explaining a method of manufacturing a semiconductor device having a deep contact structure according to one embodiment.

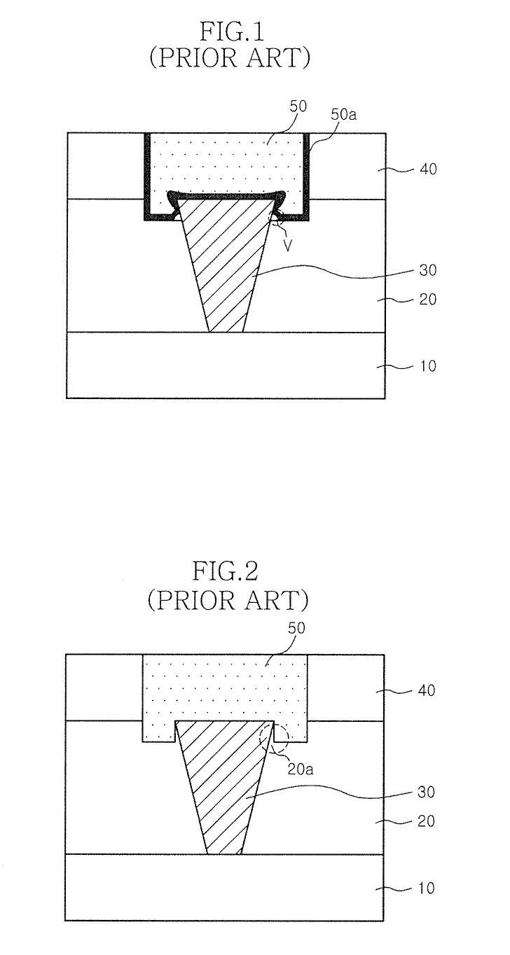

### DETAILED DESCRIPTION

Hereinafter, preferred embodiments of the present invention will be described in detail with reference to the accompanying drawings. It is understood herein that the drawings are not necessarily to scale and in some instances proportions may have been exaggerated in order to more clearly depict certain features of the invention.

A comparatively deep contact structure having a negative side wall profile will be described. A contact hole and a contact plug that will also be described below which indicates a contact hole and a contact plug having an aspect ratio relatively higher than other comparable contact holes, such as those encountered in word line contacts of phase-change memory devices.

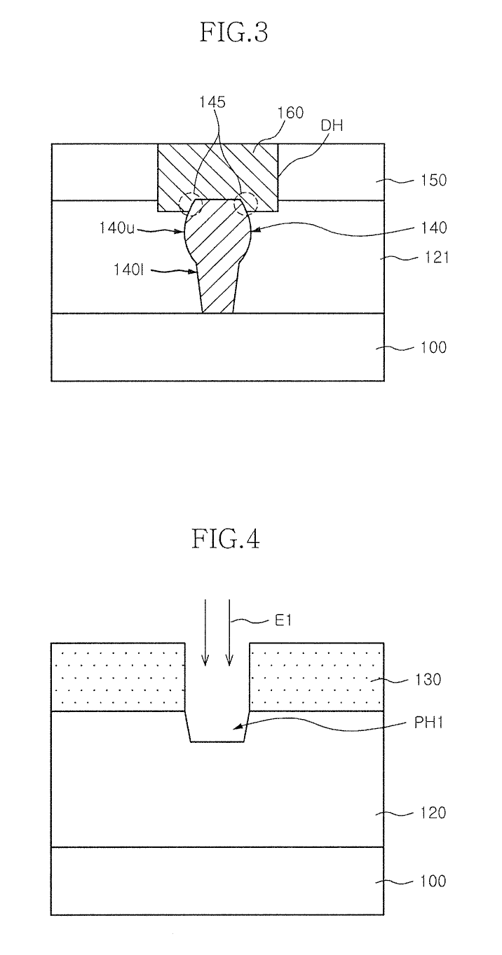

Referring to FIG. 3, the contact structure can be configured to include a first interlayer insulating layer 121 having a comparatively thick thickness that is formed on a semiconductor substrate 100. Herein, various circuit elements (not shown), various connection members (not shown) for transmitting a signal to the circuit elements, and insulating layers (not shown) for electrically insulating them from each other can additionally be interposed between the semiconductor substrate 100 and the first interlayer insulating layer 121.

A contact plug 140 having an upper side wall 140u and a lower side wall 140l is shown formed inside of the first interlayer insulating layer 121. Herein, the upper side wall 140u can have an upper portion having a bowed or bulbous shape, e.g., brought about by a prior isotropic etching step, and a lower portion having a vertical or tapered the lower side wall 140l, e.g., brought about by a prior anisotropic etching step. It is understood that the lower side wall 140l may deviate from having perfectly vertical wall along the semiconductor substrate 100, and that the requisite etching processes needed to build these particularly a deep contact structures, results in lower side walls 140l having negative slopes, i.e., downwardly tapered side walls.

A second interlayer insulating layer 150 including a damascene contact hole DH for exposing an upper surface of the contact plug 140 and a peripheral portion thereof is formed in an upper part of the first interlayer insulating layer 121 including the contact plug 140. A contact pad 160, e.g., a copper contact pad is formed in the damascene contact hole DH.

Herein, the upper surface of the contact plug 140 and a part of the upper side wall 140u are configured to protrude into the contact pad 160 and a part 145 covered with the contact pad 160 of the upper side wall 140u of the contact plug 140 is configured to have a positive slope. When the upper part of the contact plug 140 is inserted into the inside of the contact pad 160 and the inserted upper side wall part 145 has the positive slope, then voids are less likely to occur at the upper surface and the side wall of the contact plug 140 are in contact with the contact pad 160.

In this particular embodiment, it is important that the upper side wall of the contact plug 140 that protrudes into the contact pad 160 has the positive slope. As a result, a metal seed layer (not shown) forming the contact pad 160 is more evenly deposited in the upper part of the contact plug 140 and along the upper side wall part 145 having the positive slope, such that the contact pad 160 in the damascene contact hole DH is more likely to be completely filled in.

Accordingly, voids are substantially less likely to occur in the damascene contact hole DH so that all of the upper side wall of the contact plug 140 is contacts the contact pad 160 and thereby results in a reduced contact resistance.

Hereinafter, a method of manufacturing a wiring structure of a semiconductor device according to one embodiment will be described with reference to referring to FIGS. 4 to 10.

Referring to FIG. 4 a preliminary first interlayer insulating layer 120 is formed on the top of the semiconductor substrate 100. The preliminary first interlayer insulating layer 120 can use, for example, a silicon oxide film-based insulating layer and can be formed thicker than a target thickness of the first interlayer insulating layer by 500 to 700 Å, for example, with a thickness of about 5500 to 6500 Å. As a mask pattern for restricting a contact hole in the top of the preliminary first interlayer insulating layer 120, a photoresist pattern 130 is formed by using any number of well known photolithographic methods. Next, first etching ‘E1’ is performed on selected portions of the preliminary first interlayer insulating layer 120 by using the photoresist pattern 130 as a mask. Herein, the first etching ‘E1’ is preferably performed at a depth additionally deposited to the target thickness of the first interlayer insulating layer, that is, approximately 500 to 700 Å. The first etching step ‘E1’ can be performed, for example, by using an anisotropic etching method. The anisotropic etching can be performed by way of mixed gases of CF₄ gas and CHF₃ gas when the preliminary first interlayer insulating layer 120 is silicon oxide film-based. A first preliminary hole PH1 is formed in the preliminary first interlayer insulating layer 120 by the first etching step ‘E1’. At this time, the anisotropic etching represents etching the preliminary first interlayer insulating layer 120 in a substantially vertical direction to the surface of the semiconductor substrate 100 as already known. However, as noted above, due to the relatively high aspect ratio of the resultant preliminary hole produced from the first etching step, i.e., gas delivery characteristics vary depending on depth, then the preliminary hole PH1 may tend towards having an inwardly tapered, i.e., negative side wall profile which slightly decrease the width or the diameter as the preliminary hole PH1 proceeds downward.

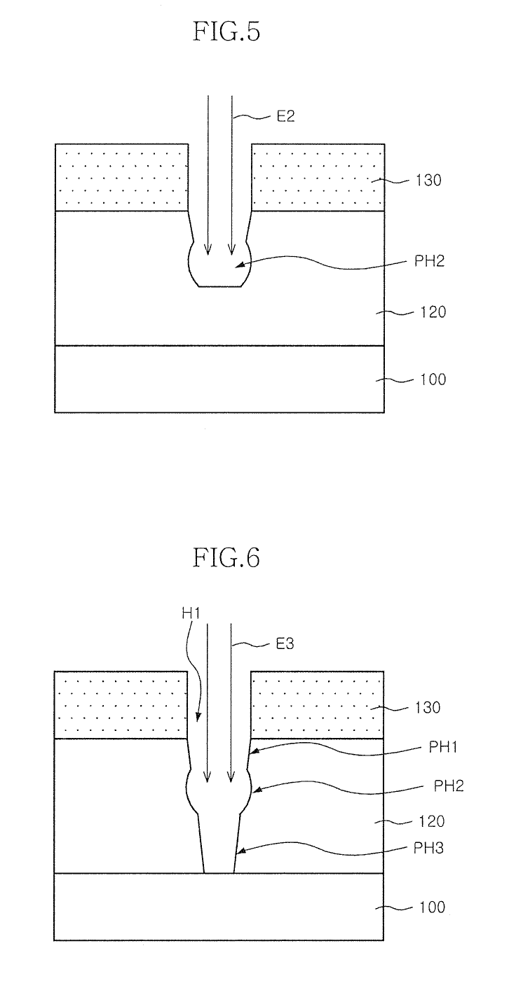

Referring now to FIG. 5, a second preliminary hole PH2 is subsequently formed by etching the preliminary first interlayer insulating layer 120 below the first preliminary hole PH1 by using a second etching step ‘E2’ which can use the same photoresist pattern 130. The second etching step ‘E2’ can be performed by using any number of well known isotropic etching techniques so that the resultant second preliminary hole PH2 has a lower side wall that has a bulbous or a bowed shape. One preferred manner of performing the second etching step ‘E2’ is to supply C₄F₈ gas at approximately 10 to 400 ssccm at a low pressure of 10 to 50 mTorr and applying a low power of between about 0 to 500 W. At this time, as the second preliminary hole PH2 is formed through the lower endpoint of the first preliminary hole PH1 by way of applying the isotropic etching method. The second preliminary hole PH2 has a resultant gradual positive slope downwards from where a juncture between the first preliminary hole PH1 and the second preliminary hole PH2 and as the bulbous side wall turns inwardly it has a the negative slope, i.e., where the top of the bulbous or bowed side wall portion of the second preliminary hole PH2 has an positive slope and the bottom of the bulbous or bowed side wall portion of the second preliminary hole PH2 has a negative slope.

Referring now to FIG. 6, a third preliminary hole PH3 is subsequently formed by etching the preliminary first interlayer insulating layer 120 through the second preliminary hole PH2 by performing a third etching step ‘E3’. This third etching step ‘E3’ results in exposing the semiconductor substrate 100 in which the same photoresist pattern 130 can again by used as the etching mask. As a result, the contact hole H1 is completely formed in the preliminary first interlayer insulating layer 120. The third etching step ‘E3’ can be any number of anisotropic etching procedures such as those similar or the same as the first etching step ‘E1’. However, since the third preliminary hole PH3 is substantially deeper than the first preliminary hole PH1, the quantity of reactant gases delivered in the third etching ‘E3’ is likely to be substantially different, usually less, than those amounts used in the first etching step ‘E1’. Therefore, the resultant side wall of the third preliminary hole PH3 is likely taper inwardly than in the side wall of the first preliminary hole PH1. That is, resultant side wall of the third preliminary hole PH3 is likely to have a more negative slope than the side wall of the first preliminary hole PH1. It is important to note that as a result of these etching steps ‘E1’, ‘E2’, and ‘E3’, a central portion of the contact hole H1 retains the bulbous or bowed shaped side wall in the preliminary first interlayer insulating layer 120 brought about by the isotropic etching in etching step ‘E2’.

Herein, in these illustrative embodiments, the preliminary first interlayer insulating layer 120 is etched so as to expose the semiconductor substrate 100 during etching for forming the resultant contact hole H1 finalized in the third etching step ‘E3’. However, it is envisioned in the present application that when a predetermined layer is interposed between the semiconductor substrate 100 and the preliminary first interlayer insulating layer 120, then the third etching step ‘E3’ may be performed until the predetermined layer in a lower part of the first interlayer insulating layer 120 is exposed and thus not exposing any portion of the underlying semiconductor substrate 100.

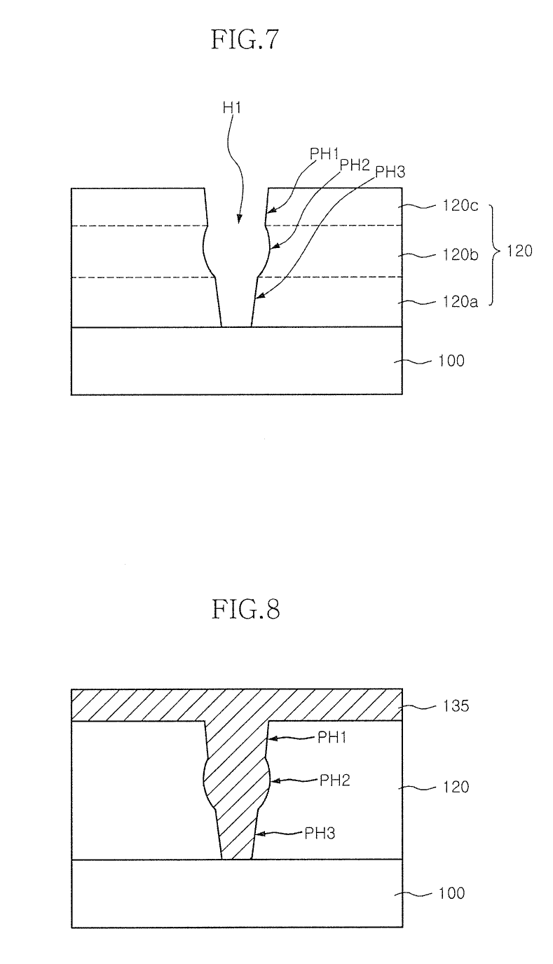

Further, in these illustrative embodiments, the contact hole H1 of the embodiment is fabricated by configuring the preliminary first interlayer insulating layer 120 by only a single layer and varying the etching method. However, it is understood herein, that the contact hole H1 of the embodiment may also be fabricated in the first interlayer insulating layer 120 though a plurality of sub-inter insulation layers, such as a first to third sub-interlayer insulating layers 120a, 120b, and 120c. Furthermore, it is understood herein, that these sub-inter insulation layers may comprise different materials that exhibit different etching properties as depicted for example in FIG. 7. One variation may be that the first and third sub-interlayer insulating layers 120a and 120c are made of a materials that are especially prone to being anisotropically etched procedure and the second sub-interlayer insulating layer 120b may be made of a material that exhibits a strong isotropic etching profile when etched. Accordingly, it is also envisioned in the present application that a single etching step can be used to build the subsequent asymmetric contact hole H1 as described above when etching a interlayer insulation layer 120 that comprises multiple sub-interlayer insulating layers.

Referring now to FIG. 8, after the photoresist pattern 130 is removed by the known method, a cleaning process is subsequently performed so as to remove most if not all of the etching residues away from the resultant surfaces. Subsequently, a burying conductive layer 135 is deposited on the top of the first interlayer insulating layer 120 so as to substantially fill in the contact hole H1. The burying conductive layer 135 can any type of conductive material such as a tungsten metal film that exhibits superior burying characteristics. Although not shown in the figure, it is understood herein, that a barrier metal film can also be formed on the surface of the result of the first interlayer insulating layer 120 including the contact hole H1 prior to depositing the burying conductive layer 135.

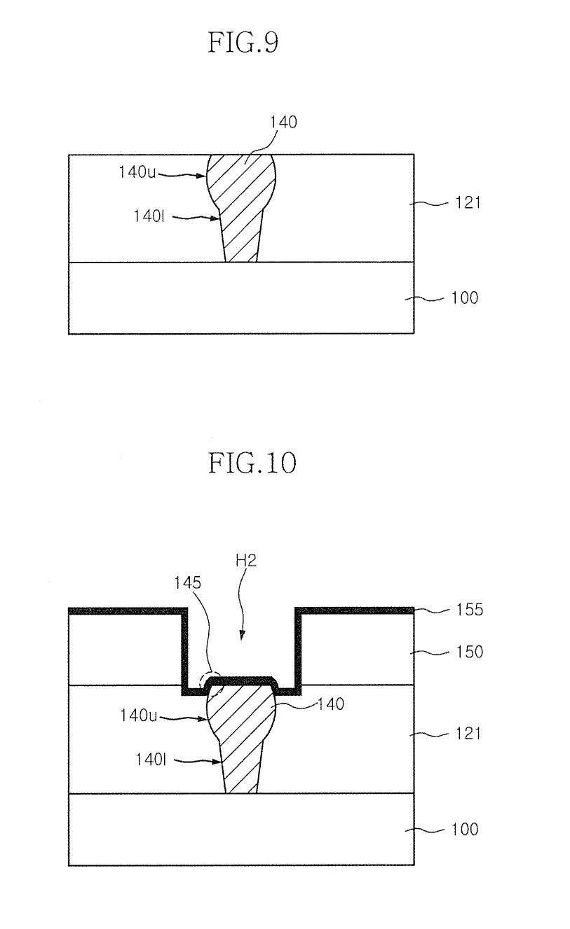

Referring now to FIG. 9, the contact plug 140 is formed by chemically and mechanically grinding the conductive layer 135 and the preliminary first interlayer insulating layer 120 up to a start point of the second preliminary hole PH2. As a result, both the conductive layer 135 remaining on the top of the preliminary first interlayer insulating layer 120 and the conductive layer 135 buried in the first preliminary hole PH1 are removed. Therefore, the preliminary first interlayer insulating layer 120 becomes a first interlayer insulating layer 121 having a target thickness. As stated before, the upper side wall 140u of the contact plug 140 is configured to have the bulbous or bowed side wall shape as that of the second preliminary hole PH2, and the lower side wall 140l of the contact plug 140 is configured to have the tapered side wall shape as that of the third preliminary hole PH3.

Referring now to FIG. 10, a second interlayer insulating layer 150 is subsequently deposited on the top of the first interlayer insulating layer 121 where the contact plug 120 is formed. The second interlayer insulating layer 150 can also be the silicon oxide film-based insulating layer such as that of the first interlayer insulating layer 120. Next, a damascene contact hole H2 is formed by selectively etching a predetermined portion of the second interlayer insulating layer 150 so as to expose the contact plug 140 and a peripheral portion next to the contact plug 140 thereof. As a result the damascene contact hole H2 is preferred to be configured to have a diameter (width) larger than the contact plug 140. In addition, it is preferable to perform excessive etching so as to partially etch into first interlayer insulating layer 121 which exposes the top surface of the contact plug 140 and exposes a part of the upper side wall 145 at the time of etching the second interlayer insulating layer 150 for forming the damascene contact hole H2. The purpose of the excessive etching is to reduce or minimize the contact resistance by increasing a contact area between the contact plug 140 and a pad to be formed thereafter. After the excessive etching, the bottom surface of the damascene contact hole H2 is positioned below a boundary surface between the first interlayer insulating layer 121 and the second interlayer insulating layer 150. As a result, the upper part of the contact plug 140 protrudes into the damascene contact hole H2.

Thereafter, it is preferred that a seed layer, such as a copper seed layer 155 is formed on the surface of the second interlayer insulating layer 150 and the surface of the damascene contact hole H2. At this time, since a side wall part 145 of the contact plug 140 that protrudes into the damascene contact hole H2 has the positive slope, then the copper seed layer 155 is more likely to be evenly formed on the surface of the damascene contact hole H2 and on the surface of the protruding contact plug 140.

On the basis of this more evenly deposited copper seed layer 155, the copper metal film is deposited on the top of the copper seed layer 155 so as to sufficiently fill up the damascene contact hole H2. Thereafter, a copper contact pad 160 (refer to FIG. 3) is formed by chemically and mechanically grinding the copper metal film so as to expose the surface of the second interlayer insulating layer 150.

As described above, according to the present invention, after forming an anisotropic preliminary hole, an isotropic preliminary hole, and the anisotropic preliminary hole from an upper part of an interlayer insulating layer, a contact plug of which an upper side wall has a positive slope is formed by removing the upper anisotropic preliminary hole. Thus, a contact pad can be formed without a void at the time of forming a follow-up contact pad.

The present invention is not limited to the foregoing embodiment.

In the embodiment, a copper metal film is described as an example of a contact pad and a tungsten film is described as an example of a contact plug, but are not limited thereto and various metal films can be used herein.

While certain embodiments have been described above, it will be understood that the embodiments described are by way of example only. Accordingly, the device and the method described herein should not be limited based on the described embodiments. Rather, the devices and methods described herein should only be limited in light of the claims that follow when taken in conjunction with the above description and accompanying drawings.

What is claimed is:

1. A semiconductor device, comprising:
a semiconductor substrate;
a first interlayer insulating layer over the semiconductor substrate;
a contact plug formed in the first interlayer insulating layer such that the contact plug comprises a bulbous shaped upper side wall; and
a contact pad formed on the top of the contact plug.

2. The semiconductor device of claim 1, wherein the contact plug further comprises an inwardly tapered lower side wall that extends downward to the semiconductor substrate, wherein the inwardly tapered lower side wall of the contact plug has a negative slope.

3. The semiconductor device of claim 1, wherein a top portion of the contact plug protrudes into the contact pad.

4. The semiconductor device of claim 3, wherein a top portion of the bulbous shaped upper side wall of the contact plug that protrudes into the contact pad have a positive slope.

5. The semiconductor device of claim 1, wherein the contact pad has a diameter larger than the contact plug.

6. The semiconductor device of claim 1, further comprising a second interlayer insulating layer on the first interlayer insulating layer such that the second interlayer insulating layer has a hole that exposes a top portion of the contact plug.

7. A semiconductor device, comprising:
a semiconductor substrate;
a first interlayer insulating layer over the semiconductor substrate;
a contact plug formed in the first interlayer insulating layer and having a bulbous shaped upper side wall and an inwardly tapered lower side wall that extends downward towards the semiconductor substrate;
a second interlayer insulating layer over first interlayer insulating layer such that the second interlayer insulating layer include a hole that exposes a top surface and a peripheral portion of the bulbous shaped upper side wall of the contact plug; and
a copper contact pad buried within the hole of the second interlayer insulating layer,
wherein the top surface and the peripheral portion of the bulbous shaped upper side wall of the contact plug protrude into the copper contact pad, and
the peripheral portion of the bulbous shaped upper side wall of the contact plug positioned in the copper contact pad have a positive slope.

8. The semiconductor device of claim 9, wherein the inwardly tapered lower side wall of the contact plug have a negative slope.

9. The semiconductor device of claim 9, wherein the first interlayer insulating layer comprises a first and a second sub-interlayer insulating layer wherein the first have an anisotropic etching property when etched in comparison to the second sub-interlayer insulating layer, and the second sub-interlayer insulating layer formed below the first sub-interlayer insulating layer has an isotropic etching property when etched in comparison to the first sub-interlayer insulating layer.

10. A method of manufacturing a semiconductor device, comprising:
forming a first interlayer insulating layer on a semiconductor substrate;
forming a contact hole in the first interlayer insulating layer such that the contact hole has a bulbous shaped upper side wall and an inwardly tapered lower side wall that extends downwards towards the semiconductor substrate;
forming a contact plug by filling up the contact hole with a metal film; and
forming a contact pad on top of the contact plug.

11. The method of manufacturing a semiconductor device of claim 10, wherein forming the contact hole includes:
forming a first preliminary hole having a inwardly tapered upper side wall that extends downward made by anisotropic etching a predetermined thickness of the first interlayer insulating layer;
forming a second preliminary hole having a bulbous shaped upper side wall side wall made by isotropic etching into the first preliminary hole of the first interlayer insulating layer; and
forming a third preliminary hole having an inwardly tapered lower side wall made by anisotropic etching into the second preliminary hole of the first interlayer insulating layer such that the third preliminary hole extends downward towards the semiconductor substrate and exposes a portion of the semiconductor substrate.

12. The method of manufacturing a semiconductor device of claim 11, wherein the step of forming the first preliminary hole comprises etching the first interlayer insulating layer using a gaseous mixture of CF₄ gas and CHF₃ gas.

13. The method of manufacturing a semiconductor device of claim 11, wherein the step of forming the second preliminary hole comprises etching the first interlayer insulating layer using a supply of C₄F₈ gas at approximately 10 to 400 ssccm and at a pressure of about 10 to 50 mTorr and at an applied power of between 0 to 500 W.

14. The method of manufacturing a semiconductor device of claim 11, wherein the step of forming the third preliminary hole comprises etching the first interlayer insulating layer using the gaseous mixture of the CF₄ gas and the CHF₃ gas.

15. The method of manufacturing a semiconductor device of claim 11, wherein the step of forming the first interlayer insulating layer comprises:
forming a lower sub-interlayer insulating layer having an anisotropic etching property on the semiconductor substrate;
forming a middle sub-interlayer insulating layer having an isotropic etching property on the lower sub-interlayer insulating layer; and
forming an upper sub-interlayer insulating layer having the anisotropic etching property on the middle sub-interlayer insulating layer.

16. The method of manufacturing a semiconductor device of claim 15, wherein the step of forming the contact hole comprises:
forming a first preliminary hole by etching into the upper sub-interlayer insulating layer by etching anisotropically the upper sub-interlayer insulating layer;
forming a second preliminary hole by etching into the middle sub-interlayer insulating layer through the first preliminary hole by etching isotropically the middle sub-interlayer insulating layer; and
forming a third preliminary hole by etching into lower sub-interlayer insulating layer through the second preliminary hole by etching anisotropically the lower sub-interlayer insulating layer.

17. The method of manufacturing a semiconductor device of claim 16, wherein the step of forming the contact plug comprises:
depositing a metal film onto the upper sub-interlayer insulating layer so as to substantially fill in the contact hole with the metal film; and
chemically and mechanically grinding the metal film and a part of the first interlayer insulating layer so as to expose an upper portion of the metal film buried in the second preliminary hole.

18. The method of manufacturing a semiconductor device of claim 10, wherein step of forming the contact pad comprises:
forming a second interlayer insulating layer on the first interlayer insulating layer and on the contact plug;
forming the hole by etching into the second interlayer insulating layer to expose an upper portion of the contact plug and to expose a periphery portion the first interlayer insulating layer that surrounds the contact plug;
forming a metal seed layer on the second interlayer insulating layer and on the exposed upper portion of the contact plug so that the metal see layer forms over an inner surface of the hole;
forming the metal film on the metal seed layer so as to substantially fill in the hole with the metal film; and
chemically and mechanically grinding the metal film so as to expose a surface of the second interlayer insulating layer.

19. The method of manufacturing a semiconductor device of claim 18, wherein the metal film is a copper metal film.

20. The method of manufacturing a semiconductor device of claim 18, wherein the forming step of the hole further comprises etching a predetermined additional thickness of the first interlayer insulating layer away from the periphery of the contact plug such that an upper part of the contact plug protrudes into the hole.
